(19) United States
(12) Patent Application Publication
(10) Pub. No.: US 2012/0250285 A1
(43) Pub. Date: Oct. 4, 2012

(54) ELECTRONIC APPARATUS

(76) Inventors: Pei-Yang Lin, Taipei (TW); Kun-Hsien Lin, Taipei (TW)

(21) Appl. No.: 13/422,972

(22) Filed: Mar. 16, 2012

Related U.S. Application Data
(60) Provisional application No. 61/468,335, filed on Mar. 28, 2011.

(51) Int. Cl. H05K 9/00; H05K 5/00

(52) U.S. Cl. 361/816

(57) ABSTRACT

An electronic apparatus includes a first casing, a shielding component, a waveguide component and an electronic component. The first casing includes a surface. The shielding component is disposed at the surface. The waveguide component is disposed at the surface and located above the shielding component. The waveguide component and the shielding component are integratedly formed. The electronic component is disposed at the surface and electrically connected to the waveguide component. The electronic apparatus can reduce manufacture cost, labor cost, and the thickness of the display screen.

### CROSS REFERENCE TO RELATED APPLICATIONS

The non-provisional patent application claims priority to U.S. provisional patent application with Ser. No. 61/468,335 filed on Mar. 28, 2011. This and all other extrinsic materials discussed herein are incorporated by reference in their entirety.

### BACKGROUND OF THE INVENTION

1. Field of Invention

The invention relates to an electronic apparatus and, more particularly, to an electronic apparatus with electromagnetic shielding.

2. Related Art

As electronic products become lighter, smaller, and thinner, circuits also become smaller and more ingenious. However, the electronic products are easier to be affected by electromagnetic interfering (EMI) from other electronic apparatuses.

FIG. 1 is a schematic diagram showing a conventional electronic apparatus. Taking a notebook computer as an example, the electronic apparatus 1 may include a host 11 and a display screen 12. The display screen 12 may include a display panel 121 to display images. A conductive shielding component 123 is usually disposed between an inner surface S of a casing 122 and the display panel 121 of the display screen 12 to prevent external EMI from affecting operation of the electronic apparatus 1.

Furthermore, the electronic apparatus 1 usually includes a wireless transmission function (such as blue-tooth or Wi-Fi). Thus, the electronic apparatus 1 further includes an antenna 124 disposed at the surface S of the casing 122, and the antenna 124 is electrically connected to the host 11 via a signal line 125 (not shown) to wirelessly communicate with external devices. The signal line 125 is usually a coaxial line and disposed at the shielding component 123.

Currently, wireless transmission is performed with the antenna 124 and the signal line 125 in the conventional electronic apparatus, and the antenna 124 and the signal line 125 are manually disposed at the surface S of the casing 122, therefore, the manufacture cost and the labor effort for the electronic apparatus 1 are increased. Moreover, the signal line 125 used for transmitting wireless signals is a coaxial line, and since the coaxial line includes certain diameter and thickness, it is difficult for the display screen 12 to become thinner.

### SUMMARY OF THE INVENTION

An electronic apparatus which can reduce manufacture cost and labor cost and decrease the thickness of a display screen is disclosed.

The electronic apparatus includes a first casing, a shielding component, a waveguide component and an electronic component. The first casing includes a surface. The shielding component is disposed at the surface. The waveguide component is disposed at the surface and located above the shielding component. The waveguide component and the shielding component are integratedly formed. The electronic component is disposed at the surface and electrically connected to the waveguide component.

As stated above, a coplanar waveguide component is used as a medium for transmitting wireless signals of an electronic apparatus, and the waveguide component and the shielding component are integratedly formed. Additionally, the electronic component (which may include an antenna) of the electronic apparatus is electrically connected to the waveguide component. Consequently, the electronic apparatus no more requires a coaxial line and the antenna to transmit wireless signals, therefore, no more effort would be spend to dispose the waveguide component and the antenna at the surface of the first casing manually.

These and other features, aspects and advantages of the present invention will become better understood with regard to the following description, appended claims, and accompanying drawings.

### BRIEF DESCRIPTION OF THE DRAWINGS

FIG. 1 is a schematic diagram showing a conventional electronic apparatus;

FIG. 2A is a schematic diagram showing an electronic apparatus in an embodiment;

FIG. 2B is a partial schematic diagram showing an electronic apparatus in an embodiment; and

FIG. 3A to FIG. 3E are partial schematic diagrams showing the electronic component and the waveguide component in different embodiments.

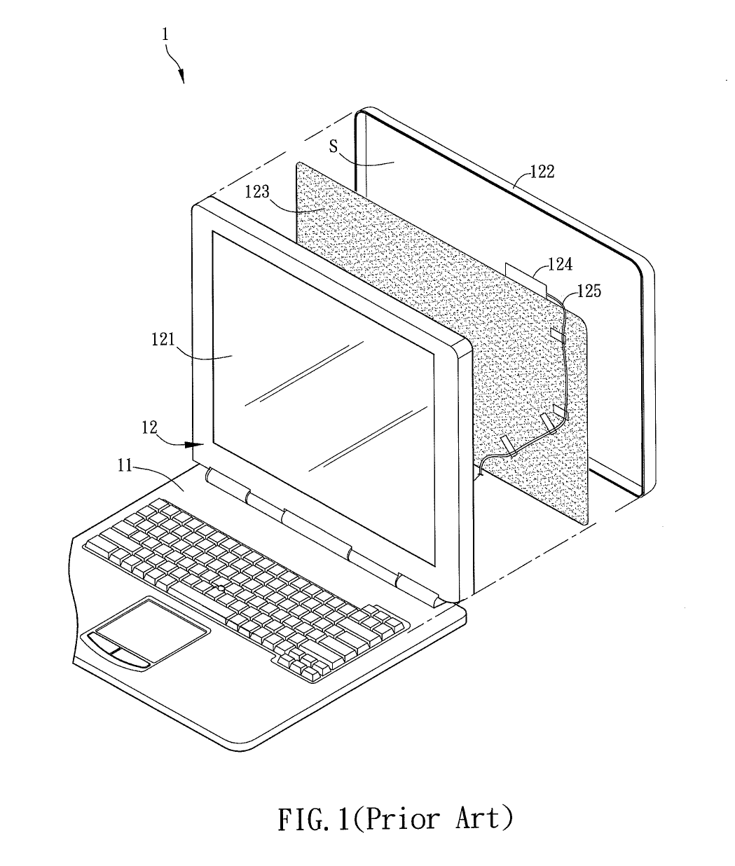

### DETAILED DESCRIPTION OF THE INVENTION

An electronic apparatus in an embodiment is illustrated with relating figures, and the same symbols denote the same components.

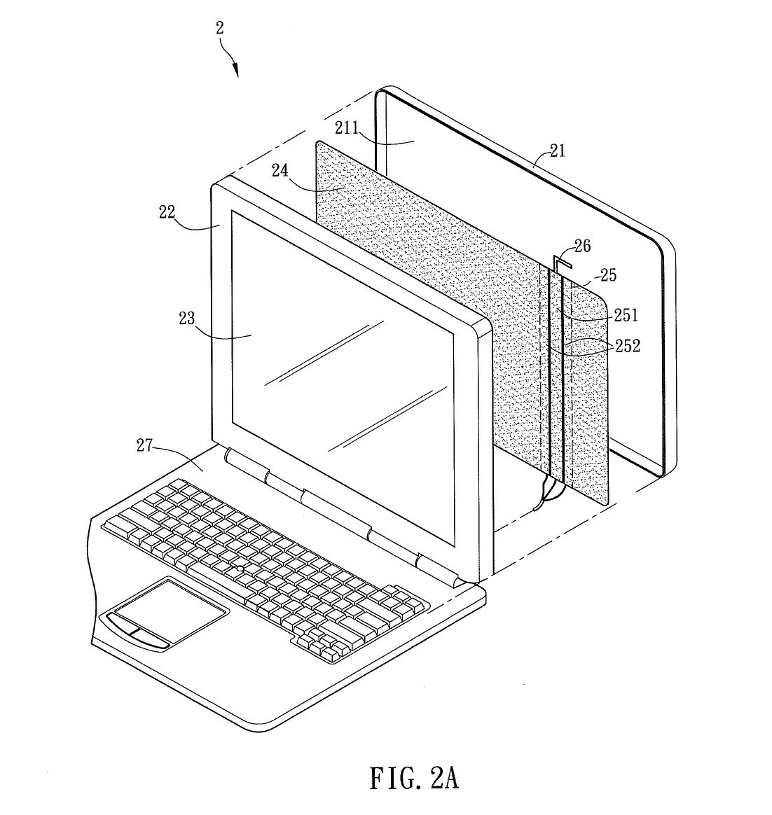

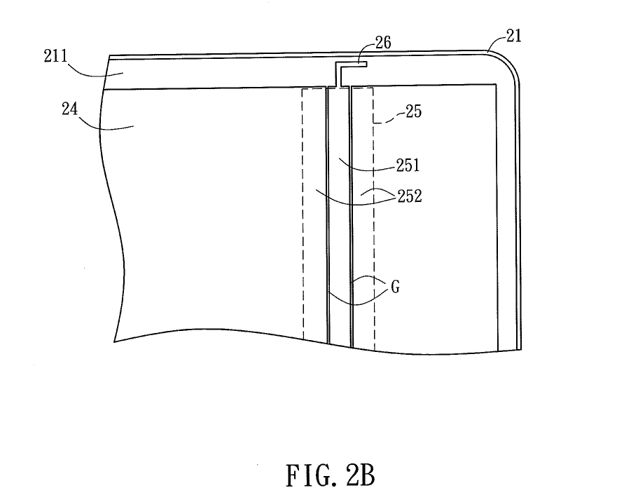

FIG. 2A is a schematic diagram showing an electronic apparatus 2 in an embodiment, and FIG. 2B is a partial schematic diagram showing an electronic apparatus 2 in an embodiment. In an embodiment, the electronic apparatus 2 may be a notebook computer, which is not limited herein.

The electronic apparatus 2 includes a first casing 21, a second casing 22 and a display panel 23. The first casing 21 and the second casing 22 form an accommodating space, and the display panel 23 is accommodated in the accommodating space.

The electronic apparatus 2 further includes a shielding component 24, a waveguide component 25 and an electronic component 26. The shielding component 24, the waveguide component 25 and the electronic component 26 are also accommodated in the accommodating space, and thus the first casing 21, the second casing 22, the display panel 23, the shielding component 24, the waveguide component 25 and the electronic component 26 form a display screen of the electronic apparatus 2 to display images.

The shielding component 24 is disposed at a surface 211 of the first casing 21. The shielding component 24 is disposed at the inner surface of the first casing 21. In an embodiment, the first casing 21 may be an insulator, such as plastic. Furthermore, the shielding component 24 may be made of high conductive material such as aluminum, copper or gold, and it may be an aluminum foil, a copper foil or a gold foil. The shielding component 24 may be disposed at the surface 211 of the first casing 21 by attaching or sputtering.

In the embodiment, the shielding component 24 is an aluminum foil which is cheap and easy to be obtained, and the shielding component 24 is attached to the surface 211 to prevent external EMI from affecting the operation of the electronic apparatus 2.

The waveguide component 25 is disposed at the surface 211 of the first casing and located above the shielding component 24. As shown in FIG. 2B, the waveguide component 25 includes a waveguide part 251 and a ground part 252 at a same plane. In the embodiment, the ground part 252 is at two sides of the waveguide part 251, and the waveguide part 251 is electrically insulated with the ground part 252 via a groove G. One end of the waveguide part 251 is a signal feed-in end, and the other end is electrically connected to an antenna to transmit wireless signals via the waveguide component 25.

In the embodiment, the waveguide component 25 belongs to a coplanar waveguide (CPW) technique. The coplanar waveguide is a planar transmission line, and its signal line (the waveguide part 251) and the ground line (the ground part 252) are at a same plane.

The electronic component 26 is disposed at the surface 211 of the first casing 21 and electrically connected to the waveguide component 25. The electronic component 26 may include an antenna, a filter, a phase adjustor, a resonance cavity or the combination.

If the electronic component 26 includes an antenna, it can be electrically connected to the waveguide component 25. If the electronic component 26 includes a filter, a phase adjustor or a resonance cavity, they may be disposed in the waveguide component 25. In the embodiment, the electronic component 26 is an antenna, and it receives the wireless signals from the waveguide component 25 and sends the signals out.

The waveguide component 25 and the shielding component 24 are integratedly formed. The waveguide part 251 and the ground part 252 are at a same plane, and the ground part 252 and the shielding component 24 are also at a same plane. In the embodiment, the waveguide component 25 and the shielding component 24 are aluminum foils, the groove G at the aluminum foil is formed via pressing and cutting, and the waveguide part 251 is in the middle and the ground part 252 is at its two sides. The waveguide part 251 is electrically insulated with the ground part 252, and the ground part 252 is electrically connected to the shielding component 24 and they are integratedly formed.

Thus, the waveguide component 25 and the shielding component 24 are formed at the aluminum foil, respectively, and the waveguide component 25 and the shielding component 24 are integratedly formed. Since the waveguide component 25 which is coplanar waveguide is used as a transmission medium to transmit wireless signals, and the waveguide component 25 and the shielding component 24 are integratedly formed, a coaxial line is no more required to transmit signals and no more effort to dispose the waveguide component 25 at the surface 211 of the first casing 21 manually. Consequently, the manufacture cost and the labor cost of the electronic apparatus 2 are reduced. Moreover, the aluminum foil is thin, which allows the display screen of the electronic apparatus 2 thinner.

The electronic component 26 (such as the antenna) can be formed by cutting an appropriate shape and size of the aluminum foil, and the electronic component 26 is physically and electrically connected to the waveguide part 251. Thus, the electronic component 26 and the waveguide component 25 are integratedly formed.

In other words, the aluminum foil is used to form the shielding component 24, the waveguide component 25 and the electronic component 26 (such as the antenna), and the shielding component 24, the waveguide component 25 and the electronic component 26 are integratedly formed. Consequently, the manufacture cost and the labor cost of the electronic apparatus 2 are further reduced, and the display screen of the electronic apparatus 2 can be thinner.

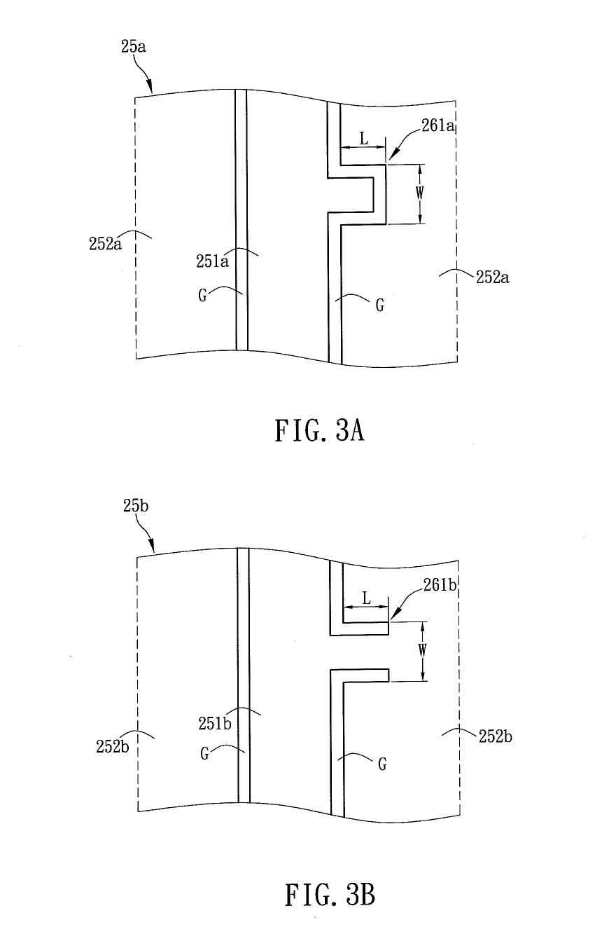

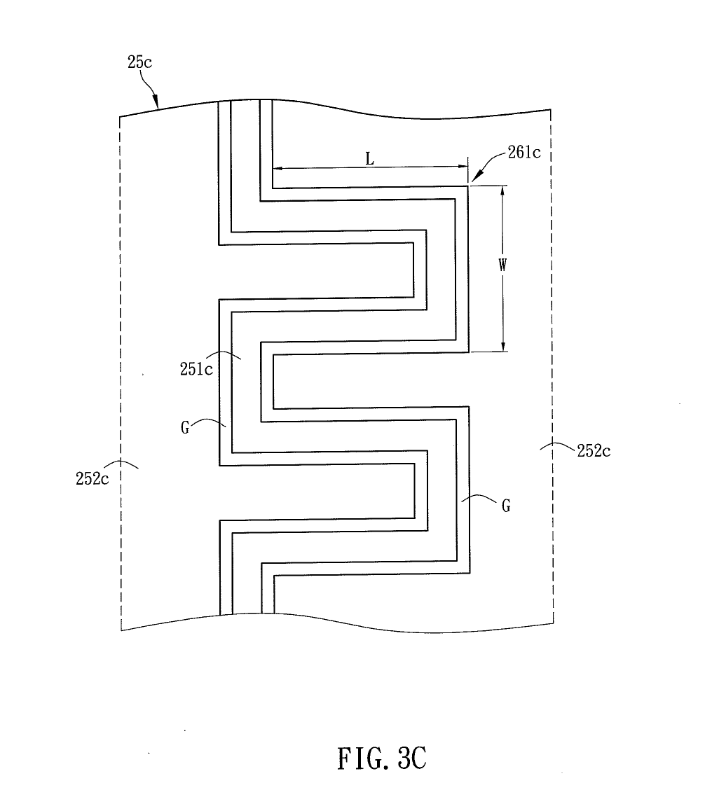

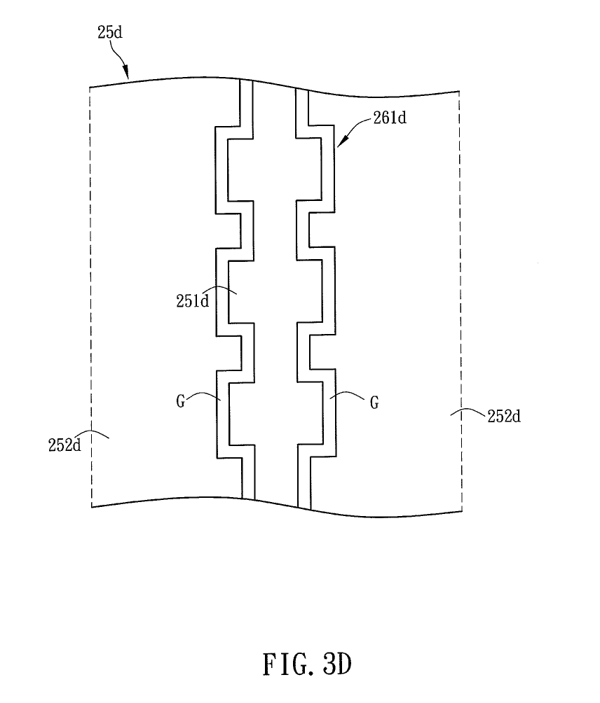

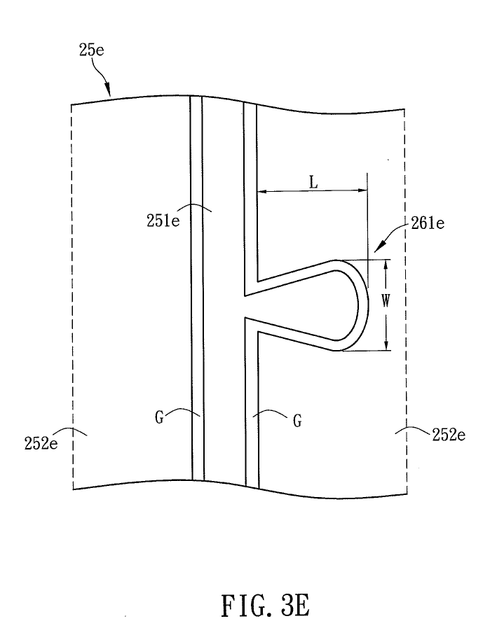

FIG. 3A to FIG. 3E are partial schematic diagrams showing the electronic component and the waveguide component in different embodiments, and the antenna, the shielding component, and the connection between the antenna and the waveguide component are not shown.

The electronic component may include an antenna, a filter, a phase adjustor and a resonance cavity or the combination. As shown in FIG. 3A, the electronic component is integrated with the waveguide component 25a and includes an antenna (not shown) and a filter 261a, and the waveguide component 25a and the filter 261a are combined. Additionally, the length L of the filter 261a can be adjusted to control the filtered frequency of the signals transmitted in the waveguide component 25a (the length L equals to a quarter of the wavelength of the frequency to be filtered), and the width W of the filter 261a can control impedance of the waveguide component 25a.

As shown in FIG. 3B, the electronic component includes an antenna (not shown) and a filter 261b, and the waveguide component 25b and the filter 261b are combined. Additionally, the length L of the filter 261b can be adjusted to control the filtered frequency of the signals transmitted in the waveguide component 25b (the length L equals to half of the wavelength of the frequency to be filtered), and the width W of the filter 261b can control impedance of the waveguide component 25b.

As shown in FIG. 3C, the electronic component includes an antenna (not shown) and a phase adjustor 261c, and the waveguide component 25c and the phase adjustor 261c are combined in shape. The width W or the length L of bent parts of the phase adjustor 261c can be adjusted to control phase difference of the transmitted signals in the waveguide component 25c.

As shown in FIG. 3D, the electronic component includes an antenna (not shown) and a filter 261d, and the waveguide component 25d and the filter 261d are combined in shape. The filter 261d may be a step impedance filter and can be regarded as a series connection of an inductor and a capacitor (LC series connection) for filtering.

As shown in FIG. 3E, the electronic component is combined with the waveguide component 25e which includes an antenna (not shown) and a filter 261e, and the waveguide component 25e and the filter 261e are combined in shape. Additionally, the length L of the filter 261e can be adjusted to filter the frequency of the signals transmitted in the waveguide component 25e (the length L equals to a quarter of the wavelength of the frequency to be filtered), and changes of the width W of the filter 261e controls impedance of the waveguide component 25e. The filtered frequency of the filter 261e is higher than that of the filter 261a in FIG. 3A, and thus the filter 261e is a broadband filter.

In FIG. 2A and FIG. 2B, the electronic apparatus 2 further includes a host 27, the host 27 is connected to the first casing 21. In detail, the host 27 is connected to the display screen. The waveguide component 25 is electrically coupled to the host 27, and the host 27 inputs signals to the signal feed-in end and the ground end of the waveguide part 251 of the waveguide component 25. The host 27 of the electronic apparatus 2 can wirelessly communicate with other electronic apparatuses via the transmission between the waveguide component 25 and the antenna (the electronic component 26). The electrically coupling may be physical wire connection or signal coupling, and the physical cable connection is taken as an example herein.

In FIG. 2 as an embodiment, the display screen and the host 27 are two separate objects and can be connected to each other to form the electronic apparatus 2. In another embodiment, the display screen and the host 27 also may be integrated as single object such as a tablet computer, a smart phone, a personal digital assistant (PDS) or a global positioning system (GPS), which is not limited herein.

In sum, the electronic apparatus can reduce the manufacture cost and the labor cost and decrease the thickness of the display screen of the electronic apparatus. Moreover, the electronic component of the electronic apparatus provides varies functions, and the waveguide component may also performed in varies aspects.

Although the present invention has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. An electronic apparatus, comprising:
a first casing including a surface;
a shielding component disposed at the surface;
a waveguide component disposed at the surface and located above the shielding component, wherein the waveguide component and the shielding component are integratedly formed; and
an electronic component disposed at the surface and electrically connected to the waveguide component.

2. The electronic apparatus according to claim 1, wherein the shielding component is made of high conductive material.

3. The electronic apparatus according to claim 1, wherein the electronic component and the shielding component are integratedly formed.

4. The electronic apparatus according to claim 1, wherein the electronic component includes an antenna, a filter, a phase adjustor and a resonance cavity or the combination thereof.

5. The electronic apparatus according to claim 1, wherein the electronic component and the waveguide component are integratedly formed.

6. The electronic apparatus according to claim 1, wherein the waveguide component includes a waveguide part and a ground part, and the waveguide part is insulated with the ground part via a groove.

7. The electronic apparatus according to claim 6, wherein the waveguide part and the ground part are at a same plane.

8. The electronic apparatus according to claim 6, wherein the ground part is electrically connected to the shielding component.

9. The electronic apparatus according to claim 1, wherein the electronic apparatus further includes:
a second casing disposed corresponding to the first casing, wherein an accommodating space is formed between the first casing and the second casing, and the shielding component, the waveguide component and the electronic component are accommodated in the accommodating space.

10. The electronic apparatus according to claim 1, wherein the electronic apparatus further includes:
a host connected to the first casing, wherein the waveguide component is electrically coupled to the host.
